(19) United States
(12) Patent Application Publication
(10) Pub. No.: US 2015/0136837 A1
(43) Pub. Date: May 21, 2015

(54) ELECTRONIC COMPONENT MOUNTING SYSTEM AND ELECTRONIC COMPONENT MOUNTING METHOD

(71) Applicant: Panasonic Intellectual Property Management Co., Ltd., Osaka (JP)

(72) Inventors: Akira Maeda, Yamanashi (JP); Kennan Mou, Yamanashi (JP); Toshihiko Nagaya, Yamanashi (JP)

(73) Assignee: Panasonic Intellectual Property Management Co., Lt, Oskaka (JP)

(21) Appl. No.: 14/404,285

(22) PCT Filed: Mar. 4, 2013
(86) PCT No.: PCT/JP2013/001325

§ 371 Date: Nov. 26, 2014

(30) Foreign Application Priority Data
Jun. 11, 2012 (JP) 2012-131617

(51) Int. Cl. H05K 13/08; B23K 3/06; B23K 1/00; H05K 3/34

(52) U.S. Cl. CPC H05K 13/08; H05K 3/3431; H05K 3/3484; B23K 3/0638; B23K 1/0016
USPC 228/102; 228/9

(57) ABSTRACT

A deformation state of a predetermined specific site as a site of singulated substrates where the electrodes are liable to be positionally deviated due to deformation is detected for each of the singulated substrates. In component mounting operation for picking up electronic components, and mounting the electronic components on the singulated substrates, it is determined whether the mounting of the electronic component on the specific site of the singulated substrates is suitable or not, based on the detection results of the deformation state for each of the singulated substrates. The operation of mounting all of the electronic components on the singulated substrate having the specific site determined to be not suitable in mounting is canceled.

### TECHNICAL FIELD

The present invention relates to an electronic component mounting system and an electronic component mounting method, which mount an electronic component on a substrate to manufacture a mounting substrate.

### BACKGROUND ART

An electronic component mounting system that mounts an electronic component on a substrate by soldering to manufacture a mounting substrate is configured by coupling a plurality of electronic component mounting devices such as a printing device that screen-prints a component joint solder paste on an electrode of the substrate, an electronic component mounting device that mounts the electronic component on the substrate on which the solder paste has been printed, and a reflow device that melts and solidifies the solder paste with each other. A target to be worked by the electronic component mounting system includes a so-called multi-surface substrate in which a plurality of film-shaped thin singulated substrates which is hard to singly deal with is held by a plate-shaped carrier, such as flexible printed substrates on which the electronic components are mounted. When the multi-surface substrate are thus targeted, since the singulated substrates are generally loaded and held on the carrier by a worker's hand, it is difficult to ensure a positional precision of electrodes to be printed over an overall surface of the multi-surface substrate. In particular, when the singulated substrates are fine-pitch resin substrates for downsized electronic devices, the difficulty becomes remarkable, and a trouble such as a printing failure caused by the positional precision is generated.

For that reason, for the purpose of preventing the trouble when the multi-surface substrate is targeted up to now, a method has been known in which it is detected whether a circuit pattern or the position is right for the singulated substrate or not, in advance, and it is appropriately determined whether a printing operation or a component mounting operation is to be executed or not, based on the detection results (for example, refer to Patent Literatures 1 and 2). In a related-art example disclosed in Patent Literature 1, if the number of positionally deviated substrates whose amount of substrate deviation calculated while recognizing the positions of the respective singulated substrates relative to the carrier (transport work) before printing is larger than a given number which is defined in advance, the printing operation on the substrates held by the carrier stops. Also, in a related-art example disclosed in Patent Literature 2, when a defect is detected in any circuit pattern in an inspection process before a multi-surface substrate on which a plurality of circuit patterns is formed is carried into an electronic component mounting equipment, a bad mark indicative of the defect is marked on the multi-surface substrate and the circuit pattern whose defect has been detected in advance, and the electronic component mounting equipment detects the bad mark to identify a defective circuit pattern.

### CITATION LIST

### Patent Literature

Patent Literature 1: JP-A-11-40999
Patent Literature 2: JP-A-2008-307830

### SUMMARY OF THE INVENTION

### Problems to be Solved by the Invention

In recent years, the resin substrates used for mounting the electronic component are developed into a thin film, and a planar shape of the resin substrates is complicated with the limitation of a layout area attributable to a downsized mobile terminal device. For that reason, the resin substrates frequently have branch portions partially branched from a related basically rectangular main body portion. Because the branch portions are extremely small in rigidity, when the singulated substrate having those branch portions are loaded into the carrier, the deformation of the branch portions makes it difficult to prevent electrodes formed around the branch portions from being positionally deviated.

However, in the related art including the above-mentioned related-art examples, a technique of coping with the positional deviation of the electrodes partially generated in the singulated substrate including the easily deformable branch portions is not established. That is, in the positional recognition of the singulated substrate which is executed prior to printing, positions of recognition marks formed on the respective singulated substrates are recognized to detect a position of the overall substrate. Therefore, when only the branch portions are partially deformed, the substrates is not determined as the defective substrate which has been positionally deviated, and the printing operation is executed as usual. For that reason, the solder paste is not correctly printed on the electrodes formed on the deformed branch portions with the results that the singulated substrates which are defectively mounted in a mounting process, and discarded after mounting frequently occur. In this way, the related art suffers from such a problem that when the plurality of singulated substrates having the easily deformable branch portions are targeted, the discarded substrates that are discarded after the mounting operation due to the defect such as the mounting failure are generated to degrade the productivity.

An object of the present invention is to provide an electronic component mounting system and an electronic component mounting method, which are capable of improving the productivity with the effective reduction of the discarded substrates even if the plurality of singulated substrates having the easily deformable branch portions are targeted.

### Means for Solving the Problems

An electronic component mounting system according to the invention is an electronic component mounting system that mounts electronic components on a multi-surface substrate having a plurality of singulated substrates to manufacture a mounting substrate, the electronic component mounting system including: a printing unit that screen-prints a component joint paste on electrodes formed on the singulated substrates for the plurality of singulated substrates in a lump; a deformation state detection unit that optically recognizes the substrate before the screen printing operation or after the screen printing operation to detect a deformation state of a predetermined specific site as a site of the singulated substrates where the electrodes are liable to be positionally deviated due to deformation for each of the singulated substrates; a component mounting unit that picks up the electronic components from a component supply unit by a mounting head, and mounts the electronic components on the singulated substrates on which the paste has been printed; a mounting control unit that controls component mounting operation by the component mounting unit; and a mounting suitability determination unit that determines whether the mounting of the electronic components on the specific site of the singulated substrates is suitable or not, based on detection results of the deformation state of the specific site for each of the singulated substrates by the deformation state detection unit, wherein the mounting control unit controls the component mounting unit to cancel the operation of mounting all of the electronic components on the singulated substrate having the specific site determined to be not suitable in mounting of the electronic components by the mounting suitability determination unit.

An electronic component mounting method according to the invention is an electronic component mounting method that mounts electronic components on a multi-surface substrate having a plurality of singulated substrates to manufacture a mounting substrate, the electronic component mounting method including: a printing step of screen-printing a component joint paste on electrodes formed on the singulated substrates for the plurality of singulated substrates in a lump by a printing unit; a deformation state detection step of optically recognizing the substrate before the screen printing operation or after the screen printing operation to detect a deformation state of a predetermined specific site as a site of the singulated substrates where the electrodes are liable to be positionally deviated due to deformation for each of the singulated substrates; a mounting suitability determination step of determining whether the mounting of the electronic components on the specific site of the singulated substrate is suitable or not, based on detection results of the deformation state of the specific site for each of the singulated substrates in the deformation state detection step; and a component mounting step of picking up the electronic components from a component supply unit by a mounting head, and mounting the electronic components on the singulated substrates on which the paste has been printed, wherein, in the component mounting step, the operation of mounting all of the electronic components on the singulated substrate having the specific site determined to be not suitable in mounting of the electronic components in the mounting suitability determination step is canceled.

### Advantage of the Invention

According to the present invention, a deformation state of a specific site predetermined as a site of the singulated substrate where the electrodes are liable to be positionally deviated due to deformation is detected for each of the singulated substrates. In component mounting operation for picking up the electronic component, and mounting the electronic component on the singulated substrate, it is determined whether the mounting of the electronic component on the specific site of the singulated substrate is suitable or not, based on the detection results of the deformation state for each of the singulated substrates. The operation of mounting all of the electronic components on the singulated substrate having the specific site determined not to be suitable in mounting is canceled, as a result of which even if the plurality of singulated substrates having the easily deformable branch portions is targeted, the productivity can be improved with the effective reduction of the discarded substrates.

### BRIEF DESCRIPTION OF THE DRAWINGS

FIG. 1 is a block diagram illustrating an overall configuration of an electronic component mounting system according to an embodiment of the present invention.

FIG. 2 is a block diagram illustrating a configuration of a screen printing device in the electronic component mounting system according to the embodiment of the present invention.

Sections (a) to (c) of FIG. 3 are illustrative views of substrate recognition and mask recognition by a screen printing device in the electronic component mounting system according to the embodiment of the present invention.

Sections (a) and (b) of FIG. 4 are illustrative views of a configuration of a multi-surface substrate to be produced by the electronic component mounting system according to the embodiment of the present invention.

Sections (a) and (b) of FIG. 5 are illustrative views of a deformation state of a singulated substrate in the multi-surface substrate to be produced by the electronic component mounting system according to the embodiment of the present invention.

FIG. 6 is a block diagram illustrating a configuration of a printing inspection device in the electronic component mounting system according to the embodiment of the present invention.

FIG. 7 is a block diagram illustrating a configuration of an electronic component mounting device in the electronic component mounting system according to the embodiment of the present invention.

FIG. 8 is a block diagram illustrating a configuration of a control system in the electronic component mounting system according to the embodiment of the present invention.

FIG. 9 is a flowchart of electronic component mounting processing on a multi-surface substrate in the electronic component mounting system according to the embodiment of the present invention.

Sections (a) and (b) of FIG. 10 are illustrative views of steps of the electronic component mounting processing on the multi-surface substrate in the electronic component mounting system according to the embodiment of the present invention.

Sections (a) and (b) of FIG. 11 are illustrative views of steps of the electronic component mounting processing on the multi-surface substrate in the electronic component mounting system according to the embodiment of the present invention.

### MODE FOR CARRYING OUT THE INVENTION

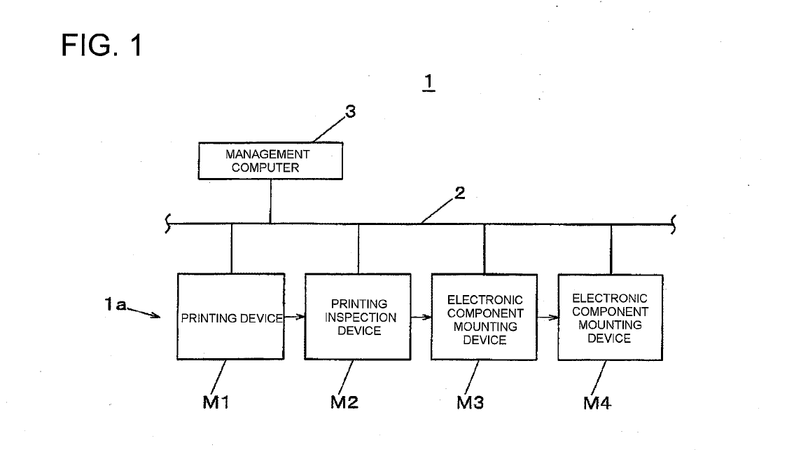

Subsequently, an embodiment of the present invention will be described with reference to the drawings. First, an overall configuration of an electronic component mounting system 1 will be described with reference to FIG. 1. Referring to FIG. 1, the electronic component mounting system 1 is configured so that the respective devices of a printing device M1, a printing inspection device M2, and electronic component mounting devices M3 and M4 each formed of an electronic component mounting device and configuring an electronic component mounting line 1a are connected to each other by a communication network 2, and the whole system 1 is integratedly controlled by a management computer 3. The electronic component mounting system 1 has a function of mounting the electronic components on a multi-surface substrate 4 having a plurality of singulated substrates 42 (refer to sections (a) and (b) of FIG. 4) by soldering to manufacture a mounting substrate. That is, the printing device M1 screen-prints a solder paste for electronic component joint on electrodes of the substrate. The printing inspection device M2 inspects a printing state of the printed solder paste. The electronic component mounting devices M3 and M4 mount the electronic components on the singulated substrates 42 on which the solder paste has been printed.

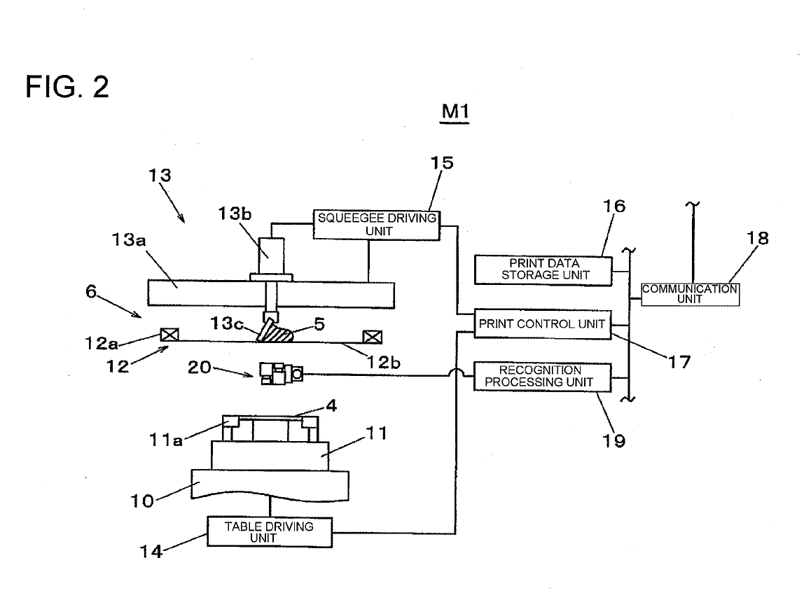

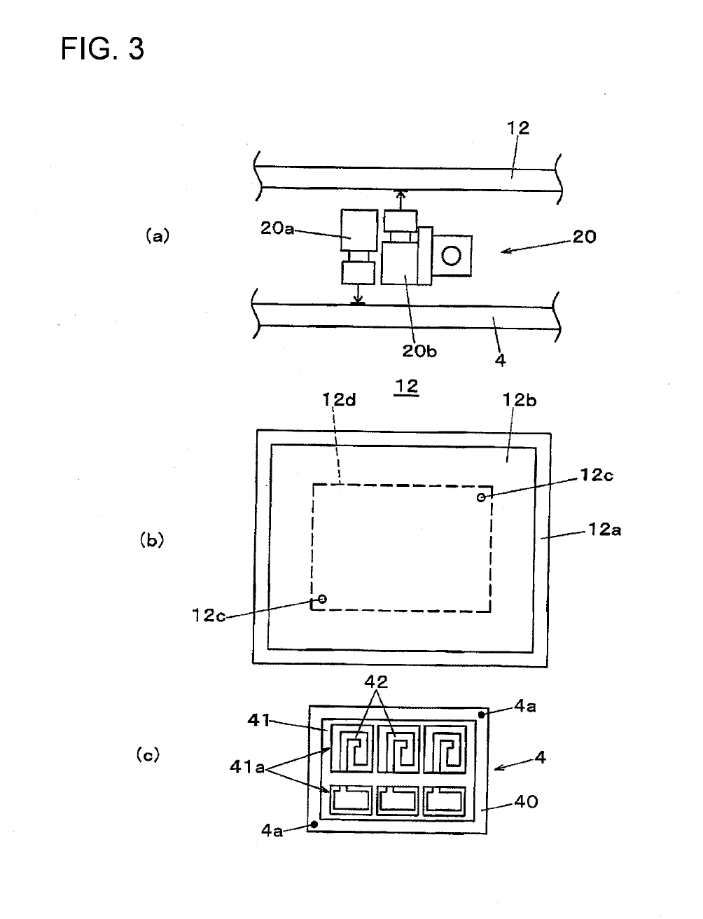

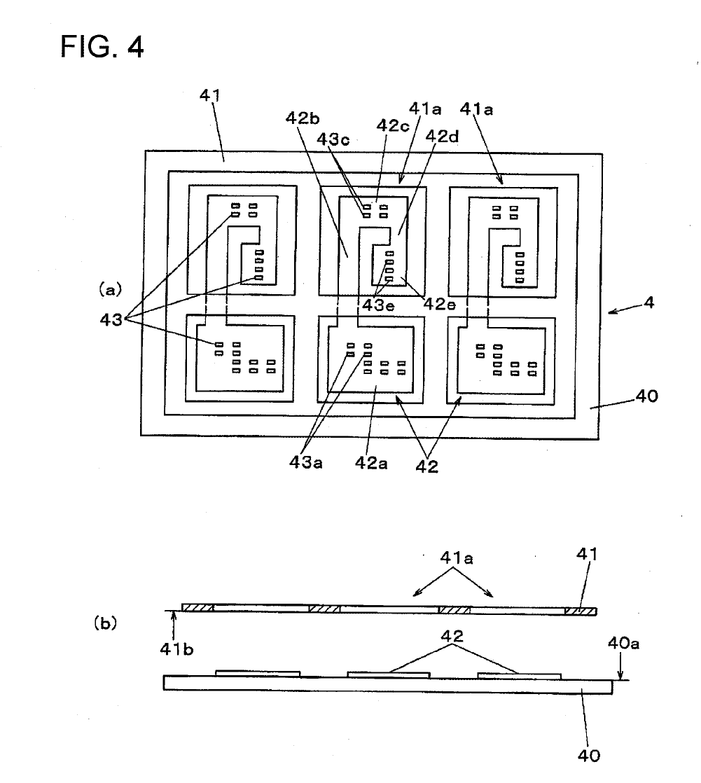

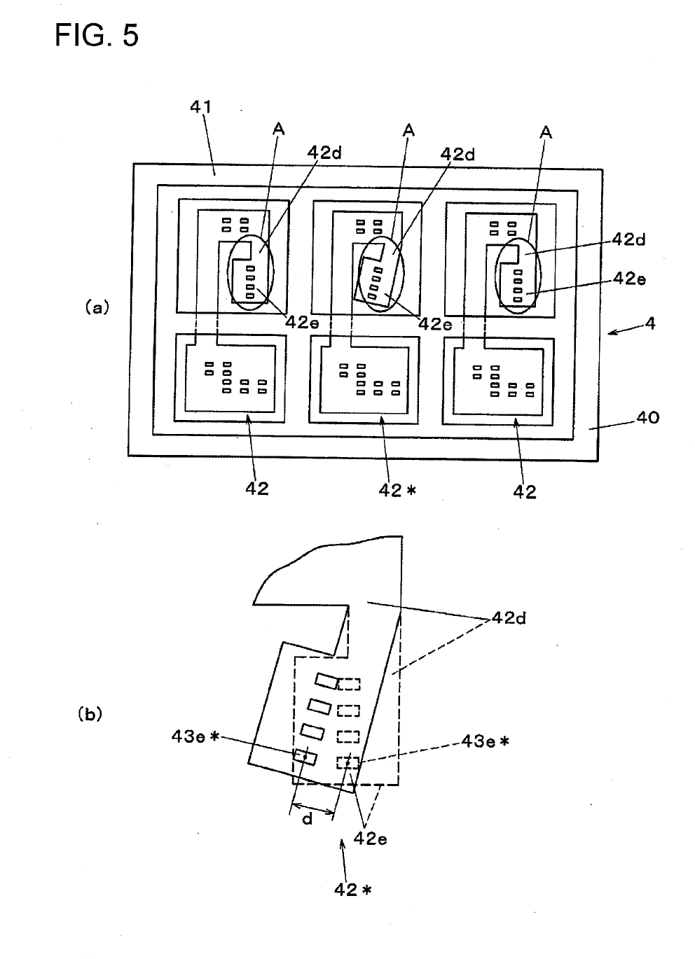

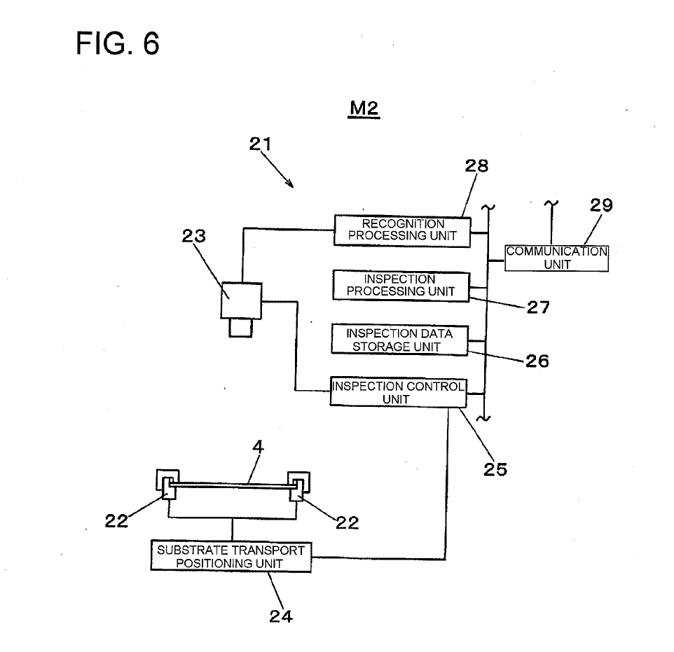

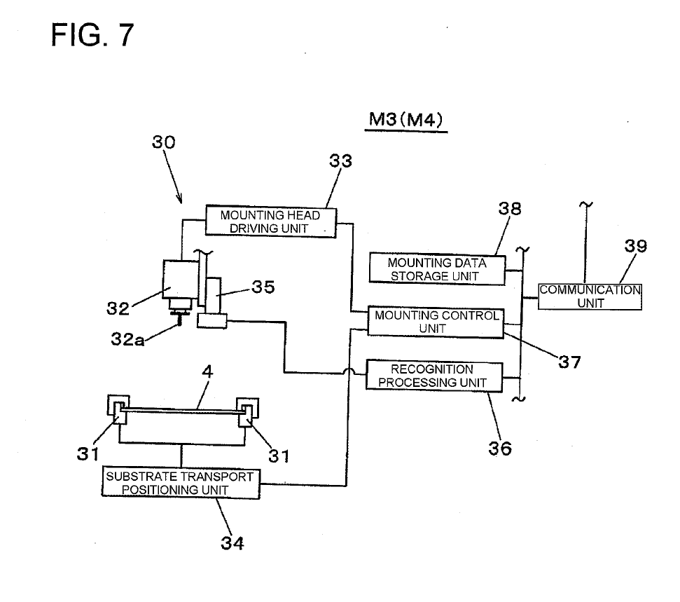

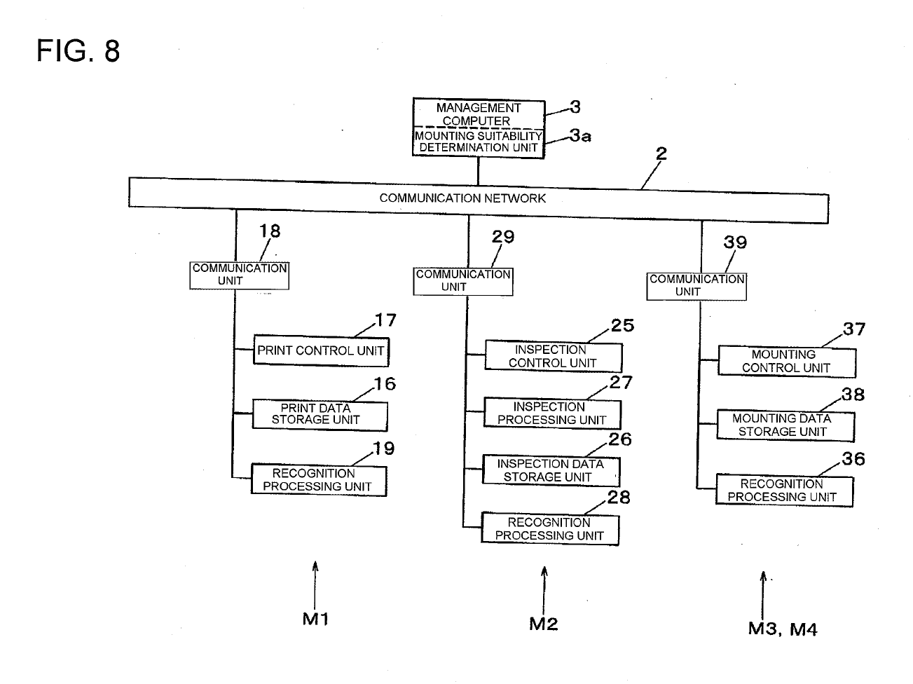

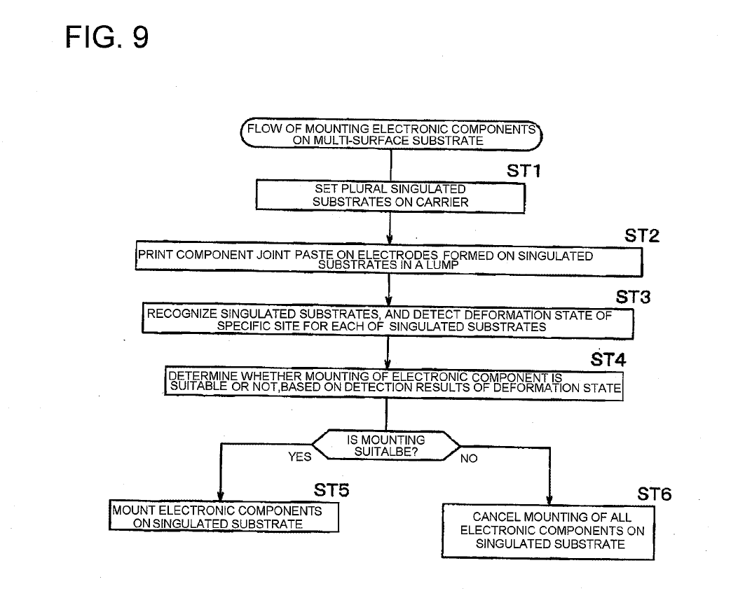

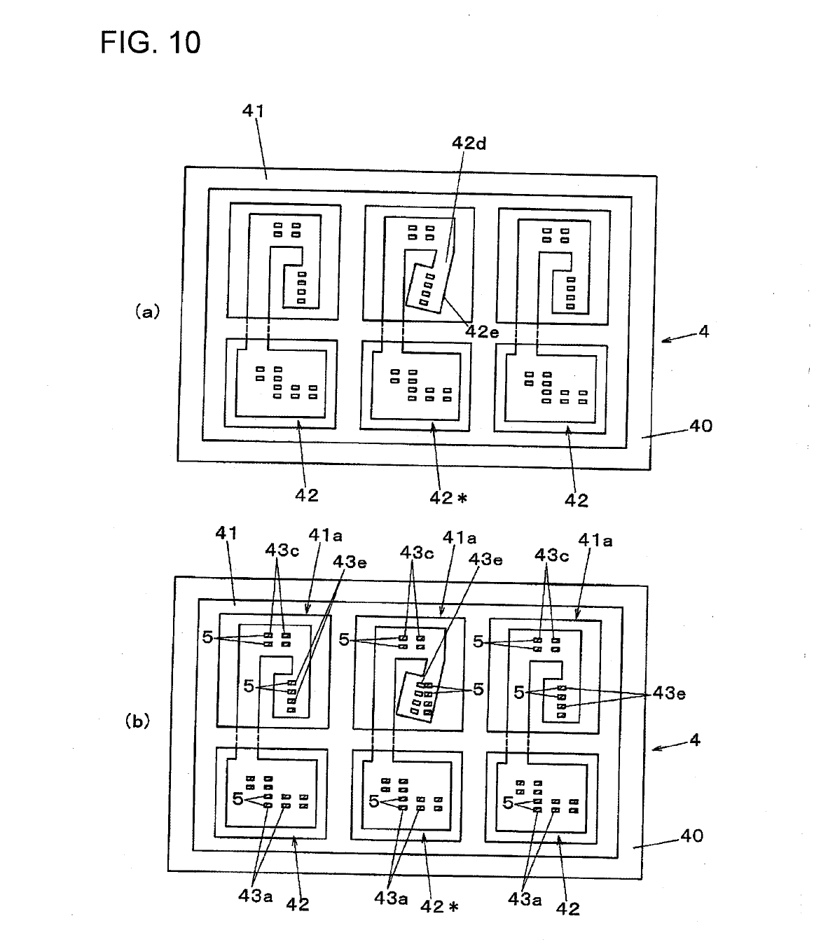

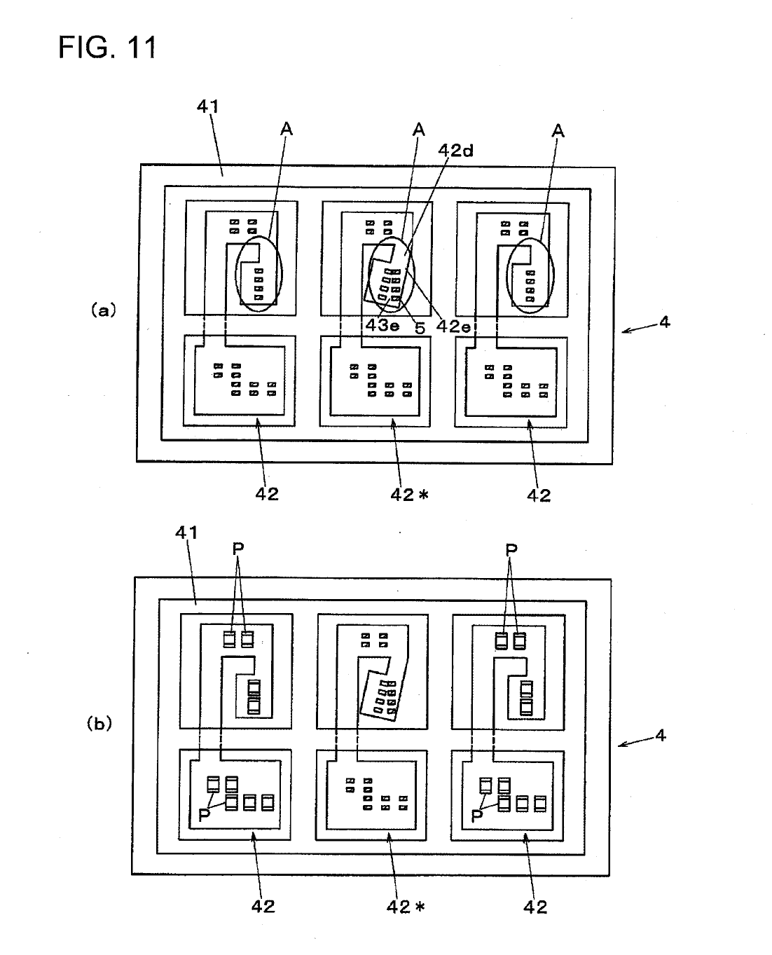

Subsequently, a configuration of the respective devices will be described. First, the configuration of the printing device M1 will be described with reference to FIG. 2. The printing device M1 has a printing unit 6 for executing the screen printing. The printing unit 6 includes a positioning table 10, a substrate holding unit 11, a screen mask 12, and a squeegee unit 13. As illustrated in FIG. 2, the substrate holding unit 11 is arranged on the positioning table 10. The substrate holding unit 11 sandwiches the substrate 4 from both sides thereof by a clamper 11a, and holds the substrate 4. A screen mask 12 (refer to section (b) of FIG. 3) configured by extending a mask plate 12b in a mask frame 12a is arranged above the substrate holding unit 11. The screen mask 12 is formed with pattern holes (not shown) corresponding to printing sites of the singulated substrates 42. The positioning table 10 is driven by a table driving unit 14 with the results that the substrate 4 relatively transfers in a horizontal direction and a vertical direction with respect to the screen mask 12.

A camera unit 20 is arranged between a lower surface of the screen mask 12 and an upper surface of the substrate 4 held by the substrate holding unit 11 so as to be movable horizontally in the X-direction and the Y-direction by a camera transfer mechanism (not shown). As illustrated in section (a) of FIG. 3, the camera unit 20 includes a substrate recognition camera 20a for imaging the substrate 4 from above, and a mask recognition camera 20b for imaging the screen mask 12 from the lower surface side.

As illustrated in section (b) of FIG. 3, a printing area 12d intended for the substrate 4 is set in the mask plate 12b. Mask recognition marks 12c are formed at diagonal positions of the printing area 12d. As illustrated in section (c) of FIG. 3, the substrate 4 to be printed is formed of a multi-surface substrate, and configured to sandwich the plurality (three in this example) of singulated substrates 42 to be printed between a plate-shaped carrier 40 and a retention member 41 so as to hold the singulated substrates 42. Screen printing opening portions 41a are formed in the retention member 41. In the printing operation, the solder paste is transferred to the singulated substrates 42 through the opening portions 41a.

The camera transfer mechanism is driven to transfer the camera unit 20, thereby being capable of imaging the mask recognition marks 12c formed in the screen mask 12, substrate recognition marks 4a formed in the substrate 4 as position reference marks, and electrodes 43 (refer to sections (a) and (b) of FIG. 4) of the respective singulated substrates 42 by the mask recognition camera 20b or the substrate recognition camera 20a. Then, the imaging results are recognized by a recognition processing unit 19, to thereby detect the positions of the mask recognition marks 12c and the substrate position reference marks (the substrate recognition marks 4a and given electrodes 43 of the singulated substrates 42).

The squeegee unit 13 is arranged above the screen mask 12. The squeegee unit 13 moves up and down a squeegee 13c with respect to the screen mask 12. The squeegee unit 13 includes an elevator pressing mechanism 13b that presses the screen mask 12 with a given pressing force (printing pressure), and a squeegee transfer mechanism 13a that transfers the squeegee 13c horizontally. The elevator pressing mechanism 13b and the squeegee transfer mechanism 13a are driven by a squeegee driving unit 15.

The squeegee 13c is transferred along a surface of the screen mask 12 to which a solder paste 5 has been supplied horizontally at a given speed in a state where the substrate 4 is abutted against the lower surface of the screen mask 12, as a result of which the solder paste 5 is printed to the electrodes 43 of all the singulated substrates 42 held on an upper surface of the carrier 40 through the pattern holes not shown, and the opening portions 41a. That is, in this embodiment, the squeegee unit 13 screen-prints the solder paste 5 for component joint on the electrodes 43 formed on the singulated substrates 42 for the plurality of singulated substrates 42 in a lump.

The above printing operation is conducted by controlling the table driving unit 14 and the squeegee driving unit 15 by a print control unit 17. In this control, the operation of the squeegee 13c and the positioning of the multi-surface substrate 4 and the screen mask 12 are controlled based on print data stored in a print data storage unit 16. A communication unit 18 conducts data transfer between the management computer 3 and the other devices configuring the electronic component mounting line 1a through the communication network 2.

Now, the configurations of the singulated substrates 42 to be worked in the electronic component mounting system 1, and the substrate 4 for treating the plurality of singulated substrates 42 will be described with reference to sections (a) and (b) of FIG. 4, and sections (a) and (b) of FIG. 5. The singulated substrates 42 are formed thinned resin substrates used for a mobile equipment. The singulated substrates 42 are formed into a complicated planar shape having notches and branch portions formed for the purpose of preventing an interference with the other components for the effective use of a space within the equipment. The singulated substrates 42 illustrated in section (a) of FIG. 4 and section (a) of FIG. 5 are each formed of an irregular substrate having a rectangular portion 42a located at a lower end portion thereof, a narrow portion 42b having a narrow width and extended from the rectangular portion 42a in one direction, an end portion 42c located at an end position remote from the rectangular portion 42a, and coupled to the narrow portion 42b, a narrow coupling portion 42d, and a bend portion 42e coupled to the end portion 42c through the coupling portion 42d, and branched downward. The rectangular portion 42a, the end portion 42c, and the bend portion 42e are formed with a plurality of electrodes 43a, 43c, and 43e, respectively.

For the purpose of treating the singulated substrates 42 having the thinned and easily deformable complicated shape, in this embodiment, as illustrated in sections (a) and (b) of FIG. 4, a given number of singulated substrates 42 are placed at given positions on a placement surface 40a of the carrier 40, and partially retained by a retention surface 41b of the retention member 41 from an upper surface side thereof to hold the shape of the singulated substrates 42. A print magnetic force by a magnet is used for the retention. In order to expose the work sites of the electrodes 43a, 43c, and 43e to be subjected to the printing or component mounting operation to above, the opening portions 41a are formed in the retention member 41 in correspondence with those work sites. Further, the narrow portion 42b is sandwiched between the carrier 40 and the retention member 41, to thereby hold the positions of the respective singulated substrates 42. As a method of holding the singulated substrates 42 on the carrier 40, a coating having an adhesive force may be formed on the placement surface 40a of the carrier 40 to adhesively hold the singulated substrates 42 onto the carrier 40.

Sections (a) and (b) of FIG. 5 illustrate a state in which the held singulated substrates 42 is partially bent and deformed on the substrate 4 thus configured, as a result of which a planar position of the site to be subjected to the printing and component mounting operation is positionally deviated. That is, because the coupling portion 42d is locally narrowed in the width, and located at a site on which the retaining effect by the retention member 41 is not exerted, the coupling portion 42d is easily deformed by an external force during treatment. Sections (a) and (b) of FIG. 5 illustrate an example in which the coupling portion 42d is deformed in a singulated substrates 42* located in the center thereof. With this deformation, as illustrated in section (b) of FIG. 5, the electrodes 43e formed on the bend portion 42e coupled with the coupling portion 42d are positionally deviated within a plane. Section (b) of FIG. 5 illustrates a state in which an electrode 43e* located on an outermost end portion is positionally deviated by the amount d of positional deviation due to the deformation.

When the electrodes 43 are positionally deviated in an operation mode of the multi-surface substrate for printing the plurality of singulated substrates 42 in a lump, the positioning of the substrate 4 relative to the screen mask 12 during the printing operation cannot cope with the local positional deviation of the electrodes 43. When the printing operation is executed in a positionally deviated state, the solder paste 5 is printed at a position deviated from the electrodes 43. Then, while the above state remains, the substrate 4 is fed to the electronic component mounting device M3 to execute the component mounting operation. When the substrate 4 is further fed to a reflow step for solder joint, a normal solder joint is not conducted because of the positional deviation of the printing position. As a result, a defective substrate is generated, and subjected to disposal.

In order to prevent the above defective substrate from occurring, in this embodiment, sites of the singulated substrates 42 at which the electrodes are liable to be positionally deviated due to the deformation, that is, sites surrounded by ovals in section (a) of FIG. 5 (areas each including the coupling portion 42d and the bend portion 42e) are regarded as predetermined specific sites A. The substrate 4 after the screen printing operation or before the screen printing operation is optically recognized to detect a deformation state of the specific sites A of the respective singulated substrates 42. The detection of the deformation state may be conducted by imaging the singulated substrates 42 before the screen printing operation or after the screen printing operation by the substrate recognition camera 20a provided in the printing unit 6 of the printing device M1, or may be conducted by optically recognizing the singulated substrates 42 using the inspection function provided in the printing inspection device M2.

Then, if the deformation state of the specific sites A exceeds a predetermined reference state, for example, if the amount of positional deviation d illustrated in section (b) of FIG. 5 is larger than a threshold value, the component mounting execution on the singulated substrate 42* corresponding to the specific site A is canceled. The specific sites A are experimentally selected taking factors for determining a deformation behavior such as a material or a shape of the target singulated substrates 42, or the electrode arrangement into consideration. Also, as a standard of the positional deviation determination, the example in which the amount of positional deviation d of the electrode 43e* located at the outermost end portion in the bend portion 42e belonging to the specific site A is used is described. Alternatively, any site that can be optically recognized and is easily positionally detected such as a corner point belonging to the specific site A can be arbitrarily selected as a standard point for positional deviation determination.

Subsequently, the printing inspection device M2 will be described with reference to FIG. 6. As illustrated in FIG. 6, the printing inspection device M2 includes a print inspection unit 21 for executing the print inspection. The print inspection unit 21 is transported by transport rails 22, and a camera 23 images the substrate 4 that has been transported and positioned at an inspection position by a substrate transport positioning unit 24, to thereby conduct a given print inspection. That is, the camera 23 is arranged above the substrate 4 held by the transport rails 22. A recognition processing unit 28 recognizes the imaging results from the camera 23, to thereby conduct an inspection of the printing state of the solder paste 5, that is, the correct/incorrect determination of whether the solder paste 5 has been correctly printed on the electrodes 43 to be printed with a specified amount of solder without the positional deviation, on the respective singulated substrates 42.

The camera 23 is movable within a horizontal plane by camera transfer means (not shown), and an arbitrary position of the substrate 4 can be inspected for each of the singulated substrates 42. Whether the recognition results by the recognition processing unit 28 are suitable or not, are determined by an inspection processing unit 27 with the use of determination data stored in an inspection data storage unit 26, and output as solder inspection result data for each of the singulated substrates 42. The output data is transferred to the management computer 3 or another device through a communication unit 29 and the communication network 2. An inspection control unit 25 controls the substrate transport positioning unit 24 and the camera 23 to control the inspection operation.

Subsequently, the electronic component mounting devices M3 and M4 will be described with reference to FIG. 7. The electronic component mounting devices M3 and M4 have the same structure, and those two devices share the component mounting operation on the respective singulated substrates 42 of a single substrate 4 with each other to execute the component mounting operation. The electronic component mounting device M3 includes a component mounting unit 30 that executes the component mounting operation. The component mounting unit 30 picks up the electronic components from a component supply unit (not shown), and mounts the electronic components on the singulated substrates 42 on which the solder paste 5 have been printed.

The substrate 4 is held by transport rails 31, and positioned by a substrate transport positioning unit 34. A mounting head 32 that is transferred by a mounting head driving unit 33 is arranged above the substrate 4 held by the transport rails 31. The mounting head 32 includes a nozzle 32a that adsorbs the electronic components. The mounting head 32 picks up the electronic components from the component supply unit by the nozzle 32a, and takes out the electronic components. Then, the mounting head 32 is transferred above the substrate 4, and moved down toward the substrate 4, to thereby mount the electronic components held by the nozzle 32a on the respective printed singulated substrates 42. In the mounting head 32, a substrate recognition camera 35 that moves integrally with the mounting head 32 is arranged so that the imaging direction is downward. The mounting head 32 is transferred so that the substrate recognition camera 35 is located above the substrate 4, to thereby allow the substrate recognition camera 35 to image an arbitrary position of the substrate 4. Then, a recognition processing unit 36 recognizes the imaging results, thereby being capable of detecting a standard point for detection of the deformation state intended for the substrate recognition marks 4a of the substrate 4, or the respective singulated substrates 42.

In the above-described mounting operation, the component mounting unit 30 is controlled by a mounting control unit 37 based on the mounting data stored in a mounting data storage unit 38, that is, mounting coordinates of the electronic components on the respective singulated substrates 42 held by the substrate 4, thereby being capable of controlling positions at which the components are mounted on the substrate 4 by the mounting head 32. A communication unit 39 conducts data transfer with respect to the management computer 3 or another device configuring the electronic component mounting line 1a through the communication network 2.

In the above configuration, the substrate recognition camera 20a and the recognition processing unit 19 provided in the printing unit 6 of the printing device M1 function as a deformation state detection unit that detects the deformation state of the specific site A of the respective singulated substrates 42. In the operation description which will be described later, an example in which the deformation state of the specific site A is detected for the singulated substrates 42 that have been screen-printed will be described. Also, even if the singulated substrates 42 are optically recognized by the use of the inspection function provided in the printing inspection device M2, the deformation state of the specific site A of the respective singulated substrates 42 can be detected. On the other hand, if the printing inspection device M2 is not arranged by the configuration of the electronic component mounting line 1a, the deformation state is detected by the substrate recognition function of the printing device M1.

Subsequently, a configuration of a control system of the electronic component mounting system 1 will be described with reference to FIG. 8. The management computer 3 illustrated in FIG. 8 receives data transferred from the respective devices configuring the electronic component mounting line 1a through the communication network 2, and outputs command data to the respective devices through the communication network 2 based on a predetermined processing algorithm. The management computer 3 is provided with a mounting suitability determination unit 3a. The mounting suitability determination unit 3a determines whether the mounting of the electronic components on the singulated substrates is suitable or not, based on the detection results of the deformation state of the specific site A by the above-described deformation state detection unit for each of the singulated substrates 42. It is needless to say that the function of the mounting suitability determination unit 3a may be mounted on the individual devices configuring the electronic component mounting line 1a.

The print data storage unit 16, the print control unit 17, and the recognition processing unit 19 provided in the printing device M1 illustrated in FIG. 2 are connected to the communication network 2 through the communication unit 18. The inspection control unit 25, the inspection data storage unit 26, the inspection processing unit 27, and the recognition processing unit 28 provided in the printing inspection device M2 illustrated in FIG. 6 are connected to the communication network 2 through the communication unit 29. Also, the mounting control unit 37, the mounting data storage unit 38, and the recognition processing unit 36 provided in each of the electronic component mounting devices M3 and M4 shown in FIG. 7 are connected to the communication network 2 through the communication unit 39.

With the above configuration, the deformation state detection results output from the recognition processing unit (or the inspection processing unit 27 of the printing inspection device M2) of the printing device M1 are transmitted to the mounting suitability determination unit 3a of the management computer 3 through the communication network 2. Then, the determination results by the mounting suitability determination unit 3a are transmitted to the mounting control unit 37 in each of the electronic component mounting devices M3 and M4 through the communication network 2. The mounting control unit 37 controls the component mounting unit 30 to cancel the mounting operation of all the electronic components on the singulated substrates 42 having the specific sites A determined to be not suitable in mounting by the mounting suitability determination unit 3a.

Hereinafter, an electronic component mounting flow on the multi-surface substrate in the electronic component mounting system 1 will be described with reference to FIG. 9, sections (a) and (b) of FIG. 10, and sections (a) and (b) of FIG. 11. This example shows a process for mounting the electronic components on the multi-surface substrate 4 having the plurality of singulated substrates 42 to manufacture the mounting substrate. Referring to FIG. 9, prior to a start of the printing operation, the plurality of singulated substrates 42 is set on the carrier 40 (ST1). That is, as illustrated in section (a) of FIG. 10, the plurality (three in this example) of singulated substrates 42 is mounted on the carrier 40, and retained from an upper side thereof by the retention member 41.

With the above configuration, the singulated substrates 42 are positionally held on the carrier 40, and an area (refer to sections (a) and (b) of FIG. 4) in which the electrodes 43 for component joint are formed in each of the singulated substrates 42 is exposed to above through each of the opening portions 41a formed in the retention member 41. In this situation, in the singulated substrate 42* located in a center thereof, the coupling portion 42d and the bend portion 42e included in the specific site A are deformed.

Subsequently, the substrate 4 that holds the singulated substrates 42 is carried in the printing device M1, and the solder paste 5 for component joint is printed on the electrodes formed on the respective singulated substrates 42 in a lump (ST2: printing step). That is, as illustrated in section (b) of FIG. 10, the solder paste 5 is printed on the electrodes 43a, 43c, and 43e of the respective singulated substrates 42. In this situation, the electrodes 43e of the singulated substrates 42* located in a center thereof are positionally deviated from a regular position by the deformation of the coupling portion 42d and the bend portion 42e, and the printed solder paste 5 is displaced from the actual electrodes 43e.

Subsequently, the respective printed singulated substrates 42 are recognized to detect the deformation state of the specific site A for each of the singulated substrates (ST3: deformation state detection step). That is, the specific sites A of the singulated substrates 42 on the substrate 4, that is, the specific sites A predetermined as sites in which the electrodes are liable to be positionally deviated due to the deformation are imaged by the substrate recognition camera 20a of the printing unit 6, to thereby detect the deformation state of the specific site A for each of the singulated substrates.

In this example, as illustrated in section (a) of FIG. 11, the deformation state is sequentially detected for the specific sites A of the respective singulated substrates 42, as a result of which the deformation state is detected in the specific site A of the singulated substrate 42* located in the center thereof, and it is detected that the solder paste 5 is printed beyond a standard amount of the positional deviation from the electrodes 43e. The detection of the deformation state may be conducted at any timing, that is, before the screen printing operation is executed by the printing device M1, or after the screen printing operation has been executed. Further, when the print inspection is executed by the printing inspection device M2 after the printing step, the detection of the deformation state may be conducted by optically recognizing the substrate 4 using the inspection function of the print inspection unit 21.

Then, the detection results of the deformation state are transmitted to the mounting suitability determination unit 3a of the management computer 3 through the communication network 2. In this example, the mounting suitability determination unit 3a determines whether the mounting of the electronic components on the specific site A of each of the singulated substrates 42 is suitable or not, based on the detection results of the deformation state of the specific site A for each of the singulated substrates 42 (ST4: mounting suitability determination step). Thereafter, the electronic components are picked up from the component supply unit by the mounting head 32, and mounted on the singulated substrates 42 on which the solder paste 5 has been printed (component mounting step).

In the component mounting step, whether the component mounting operation is executed, or not, is determined based on the determination results in the mounting suitability determination step for each of the singulated substrates 42. That is, if it is determined that the mounting is suitable (yes) in the mounting suitability determination of Step ST4, in other words, if both of the electrodes 43e and the solder paste 5 are not positionally deviated beyond a standard range in the specific site A, electronic components P are mounted for the electrodes on which the solder paste 5 has been printed in the singulated substrates 42 as illustrated in section (b) of FIG. 11 (ST5).

On the contrary, if it is determined that the mounting is not suitable (no) in the mounting suitability determination of Step ST4, in other words, if the electrodes 43e and the solder paste 5 are positionally deviated from each other, and the specific site A determined to be not suitable in mounting is provided, the operation of mounting all of the electronic components P on the singulated substrates 42* such as the singulated substrate 42* in the center thereof in section (b) of FIG. 11 is canceled (ST6). This makes it possible to prevent the generation of the defective substrate caused by mounting the electronic components on the singulated substrates 42 including the defective site on which the solder paste 5 has been printed in the positionally deviated state, and conducting a reflow. Also, this makes it possible to reduce the defective substrates as well as the discarded useless components.

As has been described above, in the electronic component mounting system and the electronic component mounting method according to this embodiment, the deformation state of the specific site A predetermined as a site of the singulated substrate 42 having the thinned and easily deformable irregular shape where the electrodes are liable to be positionally deviated due to deformation is detected for each of the singulated substrates 42. In the component mounting operation for picking up the electronic components P, and mounting the electronic components on the singulated substrate 42, it is determined whether the mounting of the electronic component P on the specific site A of the singulated substrate 42 is suitable or not, based on the detection results of the deformation state for each of the singulated substrates 42. The operation of mounting all of the electronic components P on the singulated substrates 42 having the specific site A determined to be not suitable in mounting is canceled. As a result, even if the plurality of singulated substrates having the easily deformable branch portions are to be operated in a state of the multi-surface substrate, the productivity can be improved with the effective reduction of the substrates discarded as the defective substrates, and the useless components.

The present invention has been described in detail and with reference to the specific embodiment. However, it would be apparent to an ordinary skilled person that various changes or modifications can be made without departing from the spirit and the scope of the present invention.

The present invention is based on Japanese Patent Application No. 2012-131617 filed on Jun. 11, 2012, and content thereof is incorporated herein by reference.

### INDUSTRIAL APPLICABILITY

The electronic component mounting system and the electronic component mounting method according to the present invention have such advantages that the productivity can be improved with the effective reduction of the discarded substrate even if the plurality of singulated substrates each having the easily deformable branch portion is targeted, and are useful in a field in which the electronic components are mounted on the multi-surface substrate having the plurality of singulated substrates to manufacture the mounting substrate.

### DESCRIPTION OF REFERENCE NUMERALS AND SIGNS

1 electronic component mounting system
1a electronic component mounting line
2 communication network
3 management computer
4 substrate
5 solder paste
6 printing unit
12 screen mask
13 squeegee unit
20 camera unit
20a substrate recognition camera
21 print inspection unit
23 camera
30 component mounting unit
32 mounting head
40 carrier
40 retention member
42 singulated substrate
43, 43a, 43c, 43e electrode
A specific site

1. An electronic component mounting system that mounts electronic components on a multi-surface substrate having a plurality of singulated substrates to manufacture a mounting substrate, the electronic component mounting system comprising:
a printing unit that screen-prints a component joint paste on electrodes formed on the singulated substrates for the plurality of singulated substrates in a lump;
a deformation state detection unit that optically recognizes the substrate before the screen printing operation or after the screen printing operation to detect a deformation state of a predetermined specific site as a site of the singulated substrates where the electrodes are liable to be positionally deviated due to deformation for each of the singulated substrates;
a component mounting unit that picks up the electronic components from a component supply unit by a mounting head, and mounts the electronic components on the singulated substrates on which the paste has been printed;
a mounting control unit that controls component mounting operation by the component mounting unit; and
a mounting suitability determination unit that determines whether the mounting of the electronic components on the specific site of the singulated substrates is suitable or not, based on detection results of the deformation state of the specific site for each of the singulated substrates by the deformation state detection unit,
wherein the mounting control unit controls the component mounting unit to cancel the operation of mounting all of the electronic components on the singulated substrate having the specific site determined to be not suitable in mounting of the electronic components by the mounting suitability determination unit.

2. The electronic component mounting system according to claim 1, wherein the deformation state detection unit optically recognizes the substrate by a substrate recognition camera provided in the printing unit.

3. The electronic component mounting system according to claim 1, further comprising
a print inspection unit that inspects a print state of the paste on the substrate after the screen printing operation,
wherein the deformation state detection unit optically recognizes the substrate using an inspection function of the print inspection unit.

4. An electronic component mounting method that mounts electronic components on a multi-surface substrate having a plurality of singulated substrates to manufacture a mounting substrate, the method comprising:
screen-printing a component joint paste on electrodes formed on the singulated substrates for the plurality of singulated substrates in a lump by a printing unit;
optically recognizing the substrate before the screen printing operation or after the screen printing operation to detect a deformation state of a predetermined specific site as a site of the singulated substrates where the electrodes are liable to be positionally deviated due to deformation for each of the singulated substrates;
determining whether the mounting of the electronic components on the specific site of the singulated substrate is suitable or not, based on detection results of the deformation state of the specific site for each of the singulated substrates; and
picking up the electronic components from a component supply unit by a mounting head, and mounting the electronic components on the singulated substrates on which the paste has been printed,
wherein, the operation of mounting all of the electronic components on the singulated substrate having the specific site determined to be not suitable in mounting of the electronic components is canceled.

5. The electronic component mounting method according to claim 4, wherein, in detecting the deformation state, the substrate is optically recognized by imaging the substrate through a substrate recognition camera provided in the printing unit.

6. The electronic component mounting method according to claim 4, wherein, in detecting the deformation state, the substrate is optically recognized using an inspection function of a print inspection unit that inspects a printing state of the paste on the substrate after the screen printing operation.
